(19) United States
(12) Patent Application Publication
(10) Pub. No.: US 2026/0120775 A1
(43) Pub. Date: Apr. 30, 2026

(54) INTERNAL VOLTAGE GENERATING DEVICE AND GENERATING METHOD THEREFOR

(71) Applicant: Winbond Electronics Corp., Taichung City (TW)

(72) Inventor: Chung-Zen Chen, HsinChu (TW)

(73) Assignee: Winbond Electronics Corp., Taichung City (TW)

(21) Appl. No.: 19/366,519

(22) Filed: Oct. 23, 2025

(30) Foreign Application Priority Data
Oct. 28, 2024 (TW) 113140959

(51) Int. Cl. G11C 16/30; G11C 5/14; G11C 16/34

(52) U.S. Cl. CPC G11C 16/30; G11C 5/145; G11C 16/34

(57) ABSTRACT

Disclosed are an internal voltage generating device and a generating method thereof. The internal voltage generating device includes a control circuit and a voltage generating circuit. The control circuit includes a drive strength control circuit. The drive strength control circuit is configured to generate multiple drive strength control signals based on the comparison result between the internal voltage and a reference voltage. The voltage generating circuit includes a charge pump enable control circuit and multiple charge pumps. The charge pump enable control circuit is coupled to the drive strength control circuit, and is configured to generate multiple enable signals and update the enable signals based on the drive strength control signals. The charge pumps determine the number of charge pumps to be enabled based on the enable signals, and generate pump-up voltage through the enabled charge pumps.

### CROSS-REFERENCE TO RELATED APPLICATION

This application claims the priority benefit of Taiwan application serial no. 113140959, filed on Oct. 28, 2024. The entirety of the above-mentioned patent application is hereby incorporated by reference herein and made a part of this specification.

### BACKGROUND

### Technical Field

The present disclosure relates to an internal voltage generating device and a generating method thereof, and more particularly to an internal voltage generating device and a generating method thereof capable of reducing power consumption.

### Description of Related Art

The conventional internal voltage generating device activates the charge pump when the generated internal voltage is below the target voltage, and deactivates it once the target is reached to save power. However, this design cannot reduce transient current, which remains a challenge for certain electronic devices like flash memory.

As illustrated in FIG. 1A, the flash memory cell 100 in the flash memory has a tunneling oxide ETOX, a source SA1, a drain D1, a base BK, and a gate structure consisting of a control gate CG, an oxide-nitride-oxide (ONO) structure, and a floating gate FG. During the programming operation, the source SA1 and the base BK of the flash memory cell 100 may receive a voltage of, for example, 0 volts (V), while the drain D1 of the flash memory cell 100 may receive an internal programming voltage VPPD output from an internal voltage generating device. Consequently, if the flash memory employs the conventional internal voltage generating device, there may be issues such as excessively high instantaneous programming current, potentially resulting in operational anomalies or failure to meet power-saving requirements.

### SUMMARY

The present disclosure provides an internal voltage generating device and a generating method thereof, which may reduce unnecessary power consumption.

An internal voltage generating device of the present disclosure includes a control circuit and a voltage generating circuit. The control circuit includes a drive strength control circuit. The drive strength control circuit is configured to generate multiple drive strength control signals based on the comparison result between the internal voltage and a reference voltage. The voltage generating circuit includes a charge pump enable control circuit and multiple charge pumps. The charge pump enable control circuit is coupled to the drive strength control circuit, and the charge pump enable control circuit is configured to generate multiple enable signals, and update the enable signals based on the drive strength control signals. The charge pump is coupled to a charge pump enable control circuit to receive enable signals respectively to determine the number of charge pumps to be enabled based on the enable signals, and generate a pump-up voltage through the enabled charge pumps.

The internal voltage generating method of the present disclosure includes: generating multiple enable signals based on multiple drive strength control signals, and determining the number of charge pumps to be enabled according to the enable signals, so as to generate a pump-up voltage through the enabled charge pumps; comparing an internal voltage with a reference voltage, and determining whether to update each of the multiple drive strength control signals based on the comparison result; and, when it is determined to update, updating the enable signals according to the updated drive strength control signals.

Based on the foregoing, the internal voltage generating device of the present disclosure compares the internal voltage with the reference voltage, and adjusts the number of charge pumps to be enabled according to the comparison result. Consequently, it is possible to effectively prevent unnecessary power consumption during the internal operation of the internal voltage generating device.

### BRIEF DESCRIPTION OF THE DRAWINGS

FIG. 1A illustrates the structural diagram of a flash memory cell.

FIG. 1B illustrates a characteristic curve diagram of a programming operation of the flash memory cell 100.

FIG. 2 illustrates a schematic diagram of an internal voltage generating device according to an embodiment of the present disclosure.

FIG. 3A is a schematic diagram of an internal voltage generating device according to another embodiment of the present disclosure.

FIG. 3B illustrates a schematic diagram of a voltage regulation circuit according to still another embodiment of the present disclosure.

FIG. 4 illustrates a schematic diagram of a drive strength update signal circuit according to an embodiment of the present disclosure.

FIG. 5 illustrates a schematic diagram of a flip-flop according to an embodiment of the present disclosure.

FIG. 6 illustrates a schematic diagram of a logic circuit according to an embodiment of the present disclosure.

FIG. 7 illustrates an operational waveform diagram of an internal voltage generating device according to an embodiment of the present disclosure.

FIG. 8 illustrates a flowchart of a method for generating internal voltage according to an embodiment of the present disclosure.

### DESCRIPTION OF THE EMBODIMENTS

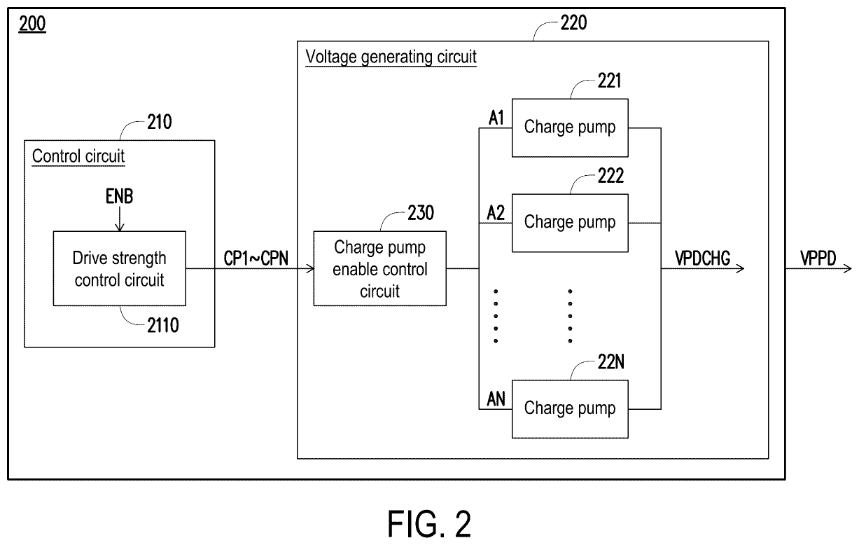

Please refer to FIG. 2. In this embodiment, the internal voltage generating device 200 is configured to generate an internal voltage VPPD based on a pump-up voltage VPDCHG, and includes a control circuit 210 and a voltage generating circuit 220. The control circuit 210 includes a drive strength control circuit 2110. The drive strength control circuit 2110 is configured to generate drive strength control signals CP1 to CPN based on the comparison result ENB between the internal voltage VPPD and a reference voltage VREF. The voltage generating circuit 220 may include a charge pump enable control circuit 230 and multiple charge pumps 221 to 22N. The charge pump enable control circuit 230 is coupled to the drive strength control circuit 2110 and is configured to generate multiple enable signals A1 to AN, and update the enable signals A1 to AN based on the drive strength control signals CP1 to CPN. The charge pumps 221 to 22N are coupled to the charge pump enable control circuit 230 to respectively receive the multiple enable signals A1 to AN to determine the number of the charge pumps 221 to 22N to be enabled based on the enable signals A1 to AN, and to generate the pump-up voltage VPDCHG through the enabled charge pumps.

According to an embodiment of the present disclosure, the control circuit 210 may dynamically adjust the drive strength of the charge pumps 221 to 22N by controlling the number of enabled charge pumps 221 to 22N. For example, when the internal voltage VPPD is greater than the reference voltage VREF, the drive strength control circuit 2110 may reduce the number of drive strength control signals CP1 to CPN in an enabled state, thereby decreasing the number of charge pumps 221 to 22N to be enabled. When the internal voltage VPPD is less than the reference voltage VREF, the drive strength control circuit 2110 may increase the number of drive strength control signals CP1 to CPN in an enabled state, thereby increasing the number of charge pumps 221 to 22N to be enabled. In an embodiment, to achieve more flexible and independent control, the number of drive strength control signals CP1 to CPN in an enabled state may be equal to the number of charge pumps 221 to 22N to be enabled. When the memory device includes the internal voltage generating device 200, the memory device may dynamically adjust the drive strength of the charge pumps 221 to 22N in response to commands for programming operations, pre-programming operations, soft programming operations, or refresh operations, thereby enhancing the operational efficiency of the internal voltage generating device 200 and avoiding unnecessary output power, thus meeting energy conservation and carbon-emission reduction requirements.

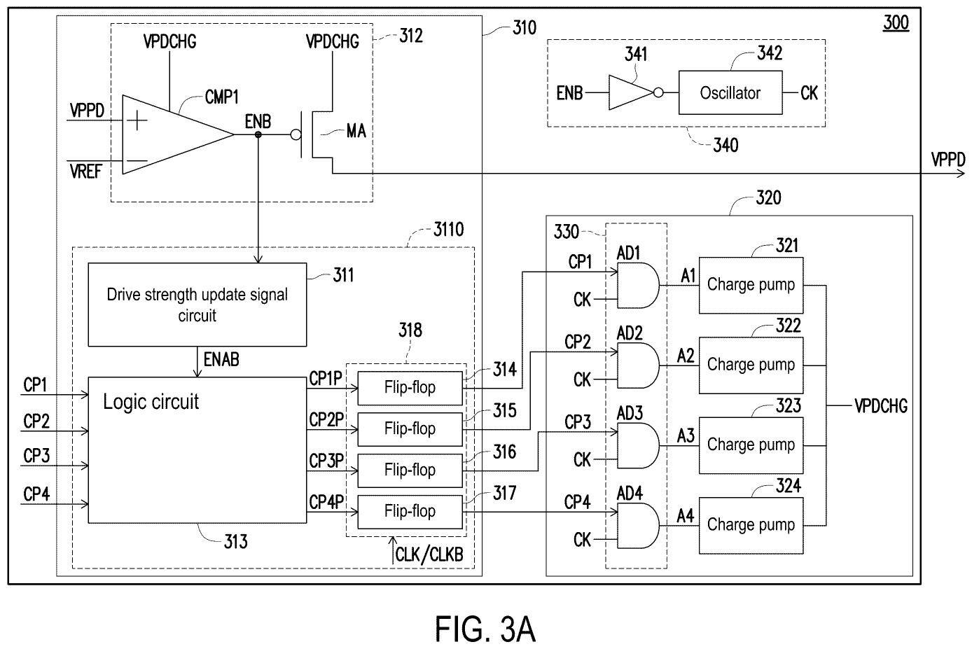

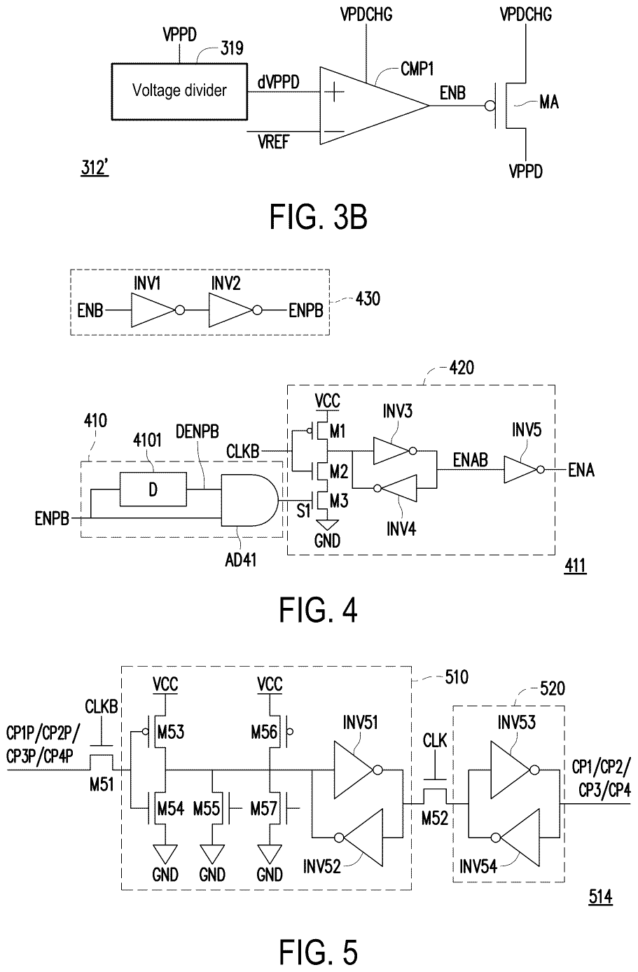

FIG. 3A illustrates the specific circuit architecture of an internal voltage generating device 300 according to an embodiment of the present disclosure. The internal voltage generating device 300 includes a control circuit 310 and a voltage generating circuit 320. The control circuit 310 may include a drive strength control circuit 3110 and a voltage regulation circuit 312. The voltage generating circuit 320 may include a charge pump enable control circuit 330 and multiple charge pumps 321 to 324.

The voltage regulation circuit 312 is configured to determine whether to utilize the pump-up voltage VPDCHG as the internal voltage VPPD based on the comparison result ENB between the internal voltage VPPD and the reference voltage VREF, and to provide the comparison result ENB to the drive strength control circuit 3110. Specifically, the voltage regulation circuit 312 may include a comparator CMP1 and a transistor MA. The comparator CMP1 may be an operational amplifier, and the comparator CMP1 may receive the pump-up voltage VPDCHG as the power supply voltage thereof. The comparator CMP1 is configured to compare the internal voltage VPPD with the reference voltage VREF, and to provide the comparison result ENB to the control terminal of the transistor MA and to the drive strength control circuit 3110. The first terminal of the transistor MA receives the pump-up voltage VPDCHG, while the second terminal of the transistor MA is configured to output the internal voltage VPPD.

In the present embodiment, when the internal voltage VPPD is greater than or equal to the reference voltage VREF, the comparator CMP1 may generate a comparison result ENB with a logic value of 1. Conversely, when the internal voltage VPPD is less than the reference voltage VREF, the comparator CMP1 may generate a comparison result ENB with a logic value of 0. Accordingly, when the internal voltage VPPD is greater than or equal to the reference voltage VREF, the transistor MA is in a cut-off state. When the internal voltage VPPD is less than the reference voltage VREF, the transistor MA is in a conductive state, thereby outputting the pump-up voltage VPDCHG as the internal voltage VPPD.

In the present embodiment, the drive strength control circuit 3110 may include a drive strength update signal circuit 311, a logic circuit 313, and a drive strength generating circuit 318. The drive strength update signal circuit 311 is coupled to the comparator CMP1 of the voltage regulation circuit 312 and is configured to receive the comparison result ENB, and detect the transition state of the comparison result ENB to generate a drive strength update signal ENAB. In the present embodiment, when the comparison result ENB transitions from a logic value of 0 to a logic value of 1, the drive strength update signal circuit 311 may correspondingly generate a drive strength update signal ENAB with a logic value of 1. In the present embodiment, the drive strength update signal circuit 311 may confirm that the comparison result ENB has stably transitioned from a logic value of 0 to a logic value of 1 before correspondingly generating the drive strength update signal ENAB with a logic value of 1.

The logic circuit 313 is configured to receive drive strength control signals CP1 to CP4 and a drive strength update signal ENAB, and generate signals CP1P to CP4P corresponding respectively to the drive strength control signals CP1 to CP4 based on the current logic values of the drive strength control signals CP1 to CP4 and the drive strength update signal ENAB. The logic circuit 313 is coupled to the drive strength generating circuit 318. The drive strength generating circuit 318 may include flip-flops 314 to 317 configured to receive the signals CP1P to CP4P respectively. The flip-flops 314 to 317 may latch the signals CP1P to CP4P respectively according to the inverted clock signal CLKB, and transmit their latched signals to update the drive strength control signals CP1 to CP4 according to the clock signal CLK.

Please note that the logic circuit 313 and flip-flops 314 to 317 may form a circuit loop. The circuit loop can update the drive strength control signals CP1 to CP4 at a frequency determined by the clock signal CLK, for example, every 100 ns.

In this embodiment, the charge pump enable control circuit 330 receives the clock signal CK and the drive strength control signals CP1 to CP4, and is configured to set the corresponding enable signals A1 to A4 to be equal to the clock signal CK when the drive strength control signals CP1 to CP4 are in an enabled state; and set the corresponding enable signals A1 to A4 to a fixed logic value when the drive strength control signals CP1 to CP4 are in a disabled state. Specifically, the charge pump enable control circuit 330 may include multiple logic gates (e.g., AND gates AD1 to AD4). The output terminals of AND gates AD1 to AD4 are respectively coupled to the charge pumps 321 to 324 and are configured to provide the enable signals A1 to A4 respectively. The internal voltage generating device 300 may further include a clock signal generating circuit 340, which is configured to generate the clock signal CK based on the comparison result ENB. The clock signal generating circuit 340 may include an oscillator 342 and an inverter 341. The inverter 341 is configured to receive the comparison result ENB, while the oscillator 342 is configured to receive the output of the inverter 341 and generate the clock signal CK accordingly. The AND gates AD1 to AD4 may respectively receive the drive strength control signals CP1 to CP4 and the clock signal CK, and generate the enable signals A1 to A4 based on the logic AND operation results.

For example, when the drive strength control signals CP1 to CP3 are in an enabled state (e.g., logic value 1), the corresponding AND gates AD1 to AD3 generate corresponding enable signals A1 to A3 through the clock signal CK, thereby enabling the corresponding charge pumps 321 to 323. In this embodiment, the clock signal CK is a clock signal with a shorter cycle than the clock signal CLK. Concurrently, the drive strength control signal CP4 is in a disabled state (e.g., logic value 0), and the corresponding AND gate AD4 may mask the clock signal CK and set the corresponding enable signal A4 to a fixed logic value (e.g., logic value 0), thereby disabling the corresponding charge pump 324.

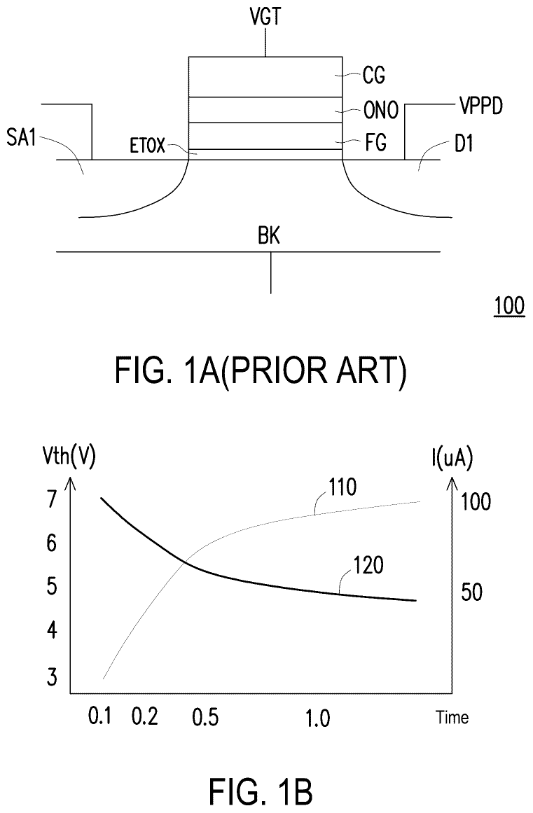

Please refer to FIG. 1B, where a curve 110 represents the change in a threshold voltage Vth of the flash memory cell 100 over time during a programming operation, and a curve 120 represents the change in a current I from the drain D1 to the source SA1 over time during the programming operation. As shown in FIG. 1B, during the programming period (i.e., the period when the internal voltage VPPD is continuously supplied to the drain D1), the threshold voltage Vth of the flash memory cell 100 gradually increases to a stable value, while the current I thereof gradually decreases to a stable value. Based on this characteristic, the present disclosure provides a flash memory including the internal voltage generating device 300, wherein the internal voltage generating device 300 may be configured to vary the driving capability for the charge pump over time during the programming operation, thereby reducing unnecessary power consumption.

Specifically, prior to the programming operation, the internal voltage generating device 300 may be configured with initial drive strength control signals CP1 to CP4, enabling the internal voltage generating device 300 to generate the internal voltage VPPD with an initial drive strength during an initial period (during the first cycle of the clock signal CLK) of the programming operation, such that the internal voltage VPPD may reach the reference voltage VREF. For instance, by enabling an initial number of charge pumps 321 to 322 through the initial drive strength control signals CP1 to CP2, the initial drive strength is set at 50%. Subsequently, during the second cycle of the clock signal CLK, it is determined whether to modify the number of charge pumps to be enabled based on the comparison result ENB. For example, when the comparison result ENB indicates that the internal voltage VPPD is less than the reference voltage VREF, the charge pumps 321 to 323 are enabled through the updated drive strength control signals CP1 to CP3, resulting in an updated drive strength of 75%. Conversely, when the comparison result ENB indicates that the internal voltage VPPD is greater than or equal to the reference voltage VREF, only the charge pump 321 is enabled through the updated drive strength control signal CP1, resulting in an updated drive strength of 25%. Thereafter, during the third cycle of the clock signal CLK, it is determined whether to modify the number of charge pumps to be enabled based on the comparison result ENB. For instance, when the comparison result ENB indicates that the internal voltage VPPD is less than the reference voltage VREF, the charge pumps 321 to 324 are enabled through the updated drive strength control signals CP1 to CP4, resulting in an updated drive strength of 100%. If the comparison result ENB indicates that the internal voltage VPPD is greater than or equal to the reference voltage VREF, only the charge pumps 321 to 322 are enabled through the updated drive strength control signals CP1 to CP2, resulting in an updated drive strength of 50%. This process continues in a similar manner. It is noteworthy that in this embodiment of the present disclosure, the internal voltage generating device may have two or more charge pumps, without any specific limitation on their number.

FIG. 3B illustrates a schematic diagram of another voltage regulation circuit 312′ of the internal voltage generating device 300 of the present disclosure. In this embodiment, the voltage regulation circuit 312′ further includes a voltage divider 319. The voltage divider 319 is configured to receive the internal voltage VPPD and perform voltage division on the internal voltage VPPD to generate a divided voltage dVPPD. The positive input terminal of the comparator CMP1 connected to the voltage divider 319, enabling it to receive the divided voltage dVPPD instead of directly receiving the internal voltage VPPD. This configuration allows the comparator to compare dVPPD with the reference voltage VREF and produce the comparison result ENB. For other details, please refer to the previous embodiment, which will not be reiterated herein. According to this embodiment, the voltage tolerance of the circuit components of the comparator CMP1 may be reduced, thereby decreasing the circuit cost of the comparator CMP1, as well as power consumption.

Referring to FIG. 4, the drive strength update signal circuit 411 of the present disclosure may include a debounce circuit 410, a latch circuit 420, and a buffer circuit 430. The buffer circuit 430 may include inverters INV1 and INV2 connected in series, and is configured to receive the comparison result ENB through the inverter INV1 and generate a buffer signal ENPB at the output terminal of the inverter INV2. The debounce circuit 410 receives the buffer signal ENPB and generates a signal S1 with a logic value of 1 when the buffer signal ENPB is stably transitioned to a logic value of 1. The latch circuit 420 receives the signal S1 and an inverted clock signal CLKB. When the signal S1 is at a logic value of 1, the latch circuit 420 may generate a drive strength update signal ENAB and an inverted drive strength update signal ENA based on the inverted clock signal CLKB.

In this embodiment, the debounce circuit 410 generates the signal S1 with a logic value of 1 only after the buffer signal ENPB has stabilized at a logic value of 1 for a delay period D. This configuration ensures the stability of the drive strength update signal ENAB. Specifically, the debounce circuit 410 may include a delay unit 4101 and an AND gate AD41. The delay unit 4101 delays the buffer signal ENPB by the delay period D to generate a delayed comparison result DENPB. The AND gate AD41 is configured to perform a logic AND operation on the delayed comparison result DENPB and the buffer signal ENPB to generate the signal S1.

The latch circuit 420 is configured such that when the inverted clock signal CLKB is at logic value 0, the drive strength update signal ENAB is set to logic value 0. When the inverted clock signal CLKB is at logic value 1, the drive strength update signal ENAB is generated based on the logic value of the signal S1, wherein the logic values of the signal S1 and the drive strength update signal ENAB may be identical at this time. Specifically, the latch circuit 420 may include transistors M1 to M3 and inverters INV3 to INV5. The transistors M1 and M2 form an inverter and are coupled between the power supply voltage VCC and the transistor M3. The inverter formed by the transistors M1 and M2 receives the inverted clock signal CLKB, and the output terminal thereof is coupled to the input terminal of the inverter INV3. The control terminal of the transistor M3 receives the signal S1, and the transistor M3 is coupled between the transistor M2 and the reference ground terminal GND. Additionally, the input terminal of the inverter INV3 is further coupled to the output terminal of the inverter INV4, while the output terminal of the inverter INV3 is coupled to the input terminal of the inverter INV4. The inverters INV3 and INV4 form a latch. The output terminal of the inverter INV3 generates the drive strength update signal ENAB, and the output terminal of the inverter INV5 generates the inverted drive strength update signal ENA. In this embodiment, the adjustment of the drive strength update signal ENAB may be performed according to the cycle of the clock signal CLK.

Please refer to FIG. 5. The flip-flop 514 may be used to implement any one of the flip-flops 314 to 317 in FIG. 3A. The flip-flop 514 includes switches formed by the transistors M51 and M52, respectively, a latch circuit 510, and a latch 520. The latch circuit 510 receives any one of the signals CP1P to CP4P (e.g., CP1P) through the transistor M51, while the transistor M52 is coupled between the latch circuit 510 and the latch 520. The transistors M51 and M52 are respectively controlled by phase-complementary inverted clock signal CLKB and the clock signal CLK. The latch circuit 510 is configured to store the received signal (e.g., CP1P) when the transistor M51 is turned on, while the latch 520 is configured to generate a corresponding drive strength control signal (e.g., CP1) by outputting the stored signal (e.g., CP1P) when the transistor M52 is turned on.

Specifically, the latch circuit 510 may include the transistors M53 to M57 and the inverters INV51 and INV52. The transistors M53 and M54 are coupled between the power supply voltage VCC and the reference ground terminal GND, forming an inverter, and receive a signal (e.g., CP1P) through the transistor M51. One terminal of the respective transistors M55, M56, and M57 is coupled to the output terminal of the inverter formed by the transistors M53 and M54. The other terminal of the respective transistors M55 and M57 are coupled to the reference ground terminal GND to provide a pull-down path, while the other terminal of the transistor M56 is coupled to the power supply voltage VCC to provide a pull-up path. The transistors M55, M56, and M57 are controlled by multiple control signals configured to set the initial state of the stored signal of the latch circuit 510. The inverters INV51 and INV52 are coupled to the output terminal of the inverter formed by the transistors M53 and M54. The inverters INV51 and INV52 are mutually coupled together to form a latch. The latch 520 includes inverters INV53 and INV54 mutually coupled together.

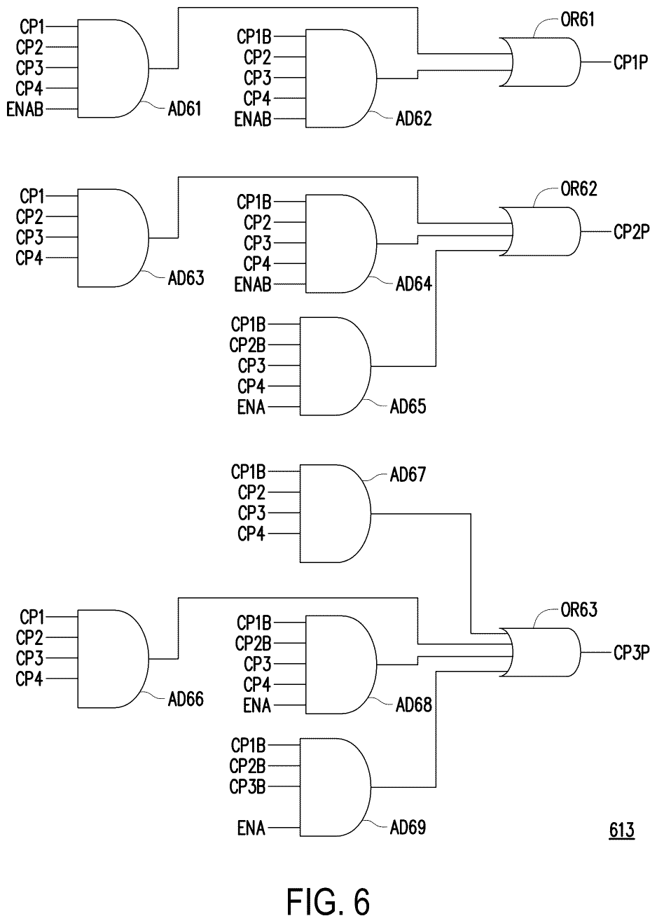

Please refer to FIG. 6. The logic circuit 613 may be used to implement the logic circuit 313 in the embodiment of FIG. 3A. The logic circuit 613 may include AND gates AD61 to AD69 and OR gates OR61 to OR63. The AND gates AD61 and AD62 as well as the OR gate OR61 are configured to generate the signal CP1P corresponding to the drive strength control signal CP1. Specifically, the AND gate AD61 receives the drive strength control signals CP1, CP2, CP3, CP4, as well as the drive strength update signal ENAB; the AND gate AD62 receives the drive strength control signals CP2, CP3, CP4, the drive strength update signal ENAB, and the inverted drive strength control signal CP1B. The OR gate OR61 receives the outputs of the AND gates AD61 and AD62, and generates the signal CP1P.

The AND gates AD63, AD64, AD65, and the OR gate OR62 are utilized to generate the signal CP2P corresponding to the drive strength control signal CP2. Specifically: the AND gate AD63 receives the drive strength control signals CP1, CP2, CP3, and CP4; the AND gate AD64 receives the drive strength control signals CP2, CP3, CP4, the drive strength update signal ENAB, and the inverted drive strength control signal CP1B; the AND gate AD65 receives the inverted drive strength control signal CP1B, the drive strength control signals CP3 and CP4, the inverted drive strength update signal ENA, and the inverted drive strength control signal CP2B. The OR gate OR62 receives the outputs from the AND gates AD63, AD64, and AD65, and subsequently generates the signal CP2P.

The AND gates AD66 to AD69, and the OR gate OR63 are utilized to generate the signal CP3P corresponding to the drive strength control CP3. Specifically, the AND gate AD66 receives the drive strength control signals CP1, CP2, CP3, and CP4; the AND gate AD67 receives the drive strength control signals CP2, CP3, CP4, and the inverted drive strength control signal CP1B; the AND gate AD68 receives the inverted drive strength control signals CP1B and CP2B, the drive strength control signals CP3 and CP4, and the inverted drive strength update signal ENA; the AND gate AD69 receives the inverted drive strength control signals CP1B and CP2B, the inverted drive strength update signal ENA, and the inverted drive strength control signal CP3B. The OR gate OR63 receives the outputs from the AND gates AD67 to AD69 and generates the signal CP3P. Furthermore, the logic circuit 613 may equate the signal CP4P with the drive strength control signal CP4, thereby generating the signal CP4P.

It is noteworthy that the logic operations of the logic circuit 613 may be represented by the following truth table:

| W1 | CP1 | CP2 | CP3 | CP4 | ENAB | W2 | CP1 | CP2 | CP3 | CP4 |
|---|---|---|---|---|---|---|---|---|---|---|
| 100% | H | H | H | H | L | 100% | H | H | H | H |
| | | | | | H | 75% | L | H | H | H |
| 75% | L | H | H | H | L | 100% | H | H | H | H |
| | | | | | H | 50% | L | L | H | H |
| 50% | L | L | H | H | L | 75% | L | H | H | H |
| | | | | | H | 25% | L | L | L | H |
| 25% | L | L | L | H | L | 50% | L | L | H | H |
| | | | | | H | 25% | L | L | L | H |

In the truth table provided above, W1 represents the current drive strength of the internal voltage generating device 300 in accordance with the present drive strength control signals CP1 to CP4. W2 represents the updated drive strength of the internal voltage generating device 300 after the adjustment (update) of the drive strength control signals CP1 to CP4. The drive strength control signals CP1 to CP4 on the left side denote the logic values of the current drive strength control signals CP1 to CP4, while the drive strength control signals CP1 to CP4 on the right side denote the logic values of the updated drive strength control signals CP1 to CP4. Herein, H represents logic value 1, and L represents logic value 0.

It is noteworthy that, to ensure the output power of the internal voltage generating device 300 meets at least a minimum required value, the drive strength control signal CP4 may be maintained at logic value 1 (H), thereby enabling the internal voltage generating device 300 to correspondingly provide at least 25% of the output power thereof.

In this embodiment, consequently, the adjustment operations of the drive strength control signals CP1 to CP4 may also be conducted based on the cycle of the clock signal CLK.

It is noteworthy that in this implementation, the AND gates AD61 to AD69 and the OR gates OR61 to OR63 may be substituted with logic gates capable of performing equivalent logic operations. Such substitution methods are commonly known to those skilled in the art of digital circuit design. In other words, the circuit architecture of the logic circuit 613 in this embodiment is merely an illustrative example and should not be construed as limiting the scope of implementation of the present disclosure.

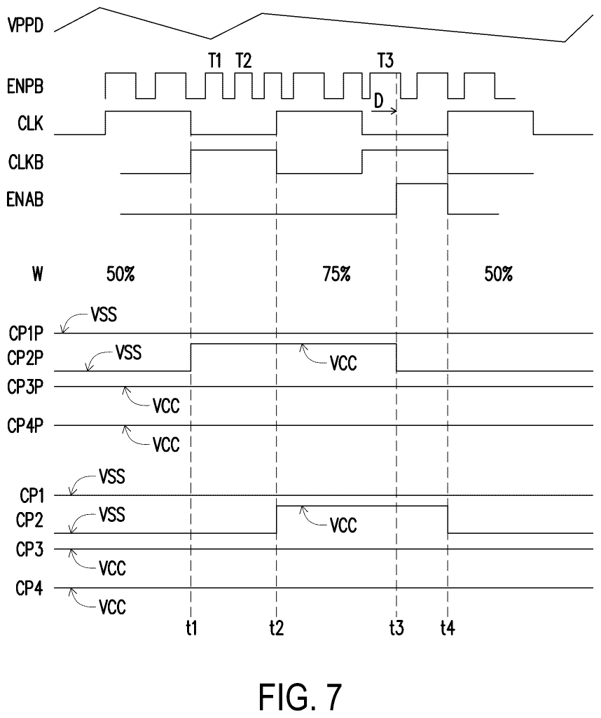

Please refer to FIG. 4 through FIG. 7 concurrently, wherein FIG. 7 illustrates the operational waveform of the internal voltage generating device 300 in an embodiment of the present disclosure. As the drive strength control signals CP1 to CP4 are updated, the number of charge pumps to be enabled and utilized for generating the internal voltage VPPD may be correspondingly adjusted.

In FIG. 7, prior to time point t1, the drive strength control signals CP1 to CP4 are set to their default (initial) logic values of 0, 0, 1, and 1, respectively. Consequently, charge pumps 323 and 324 are enabled, generating an internal voltage VPPD at 50% of drive strength W. Meanwhile, the signals CP1P to CP4P, which correspond to the drive strength control signals CP1 to CP4, respectively are logic values of 0, 0, 1, and 1. The logic value 0 corresponds to the ground voltage VSS, while logic value 1 corresponds to the power supply voltage VCC. At time point t1, the logic circuit 613 may alter the signal CP2P to logic value 1 based on the drive strength update signal ENAB (which is at logic value 0). At time point t2, corresponding to the rising edge of the clock signal CLK, the drive strength control signal CP2 transitions to logic value 1 in accordance with the signal CP2P. Consequently, after time point t2, based on the drive strength control signals CP1 to CP4 having respective logic values of 0, 1, 1, and 1, the charge pumps 322, 323, and 324 are enabled, thereby generating internal voltage VPPD at 75% of the drive strength W.

It is noteworthy that between time points t1 and t2, based on the comparison result ENB, the buffer signal ENPB generates two pulses with pulse widths T1 and T2. In this embodiment, since both pulse widths T1 and T2 are less than the delay time D provided by the debounce circuit 410, the two pulses are disregarded. Consequently, the buffer signal ENPB is considered to maintain a logic value of 0 between the time points t1 and t2.

Prior to the time point t3, the buffer signal ENPB exhibits a pulse with a pulse width of T3, where the pulse width T3 is greater than the delay time D. Consequently, the drive strength update signal ENAB transitions to a logic value of 1. Based on the drive strength update signal ENAB being at logic value 1, the signal CP2P is pulled down to logic value 0. Correspondingly, at time point t4, in response to the rising edge of the clock signal CLK, the drive strength control signal CP2 is adjusted to logic value 0, thereby enabling the charge pumps 323 and 324 to generate the internal voltage VPPD at 50% of the drive strength W.

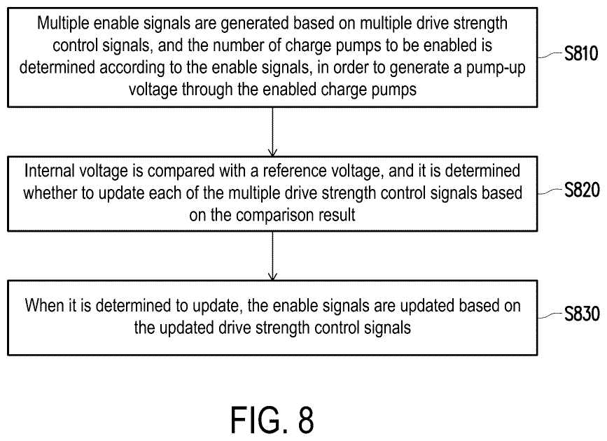

Please refer to FIG. 8, which illustrates a flowchart of a generating method of the internal voltage according to an embodiment of the present disclosure. Specifically, in step S810, multiple enable signals are generated based on multiple drive strength control signals, and the number of charge pumps to be enabled is determined according to the enable signals, in order to generate a pump-up voltage through the enabled charge pumps. In step S820, the internal voltage is compared with a reference voltage, and it is determined whether to update each of the multiple drive strength control signals based on the comparison result. The internal voltage may be periodically compared with the reference voltage, and it may be determined whether the value of the comparison result remains unchanged within a delay time D. The enable signals are updated only when the value of the comparison result remains unchanged within the delay time D. Furthermore, in an embodiment, in response to a command for a programming operation, pre-programming operation, soft programming operation, or refresh operation, multiple initial drive strength control signals may be read from a non-volatile storage element of the memory device, and multiple enable signals may be generated based on these initial drive strength control signals at the beginning of the aforementioned command. In step S830, when it is determined to update, the enable signals are updated based on the updated drive strength control signals.

Regarding the implementation details of the aforementioned steps S810 to S830, a comprehensive explanation has been provided in the preceding embodiment. Therefore, further elaboration herein is respectfully omitted.

In light of the foregoing, the internal voltage generating device of the present disclosure employs multiple charge pumps connected in parallel to collectively generate an internal voltage. Furthermore, the control circuit generates multiple drive strength control signals based on the comparison result between the internal voltage and a reference voltage. The drive strength control signals independently control the enable status of the charge pumps, thereby adjusting the number of charge pumps to be enabled. The internal voltage generating device of the present disclosure instantly monitors the comparison result between the internal voltage and the reference voltage, and dynamically adjusts the drive strength control signals to optimize power consumption of the internal voltage generating device, thereby enhancing the operational performance of internal memory operations. In some embodiments, when flash memory utilizes the internal voltage generating device of the present disclosure, it is possible to reduce programming current and power consumption. Consequently, the internal voltage generating device of the present disclosure constitutes an environmentally friendly semiconductor technology.

What is claimed is:

1. An internal voltage generating device, comprising:
a control circuit, comprising a drive strength control circuit, wherein the drive strength control circuit is configured to generate a plurality of drive strength control signals based on a comparison result between an internal voltage and a reference voltage; and
a voltage generating circuit, comprising a charge pump enable control circuit and a plurality of charge pumps, wherein the charge pump enable control circuit is coupled to the drive strength control circuit, and the charge pump enable control circuit is configured to generate a plurality of enable signals, and update the plurality of enable signals based on the plurality of drive strength control signals, the plurality of charge pumps are coupled to the charge pump enable control circuit to respectively receive the plurality of enable signals to determine the number of the plurality of charge pumps to be enabled based on the plurality of enable signals, and generate a pump-up voltage through the plurality of enabled charge pumps.

2. The internal voltage generating device according to claim 1, wherein output terminals of the plurality of charge pumps are coupled to each other.

3. The internal voltage generating device according to claim 1, wherein the control circuit further comprises a voltage regulation circuit, which is configured to compare the internal voltage with the reference voltage, and determine whether to utilize the pump-up voltage as the internal voltage based on the comparison result, and to provide the comparison result to the drive strength control circuit.

4. The internal voltage generating device according to claim 1, further comprising:
a clock signal generating circuit, configured to generate a first clock signal based on the comparison result,
wherein the control circuit equates each of the corresponding enable signals to the first clock signal when each of the drive strength control signals is in an enabled state; the control circuit sets each of the corresponding enable signals to a fixed logic value when each of the drive strength control signals is in a disabled state.

5. The internal voltage generating device according to claim 1, wherein when the internal voltage is greater than the reference voltage, the drive strength control circuit reduces the number of the plurality of drive strength control signals in an enabled state; when the internal voltage is less than the reference voltage, the drive strength control circuit increases the number of the plurality of drive strength control signals in the enabled state.

6. The internal voltage generating device according to claim 1, wherein the number of the plurality of drive strength control signals in an enabled state is equal to the number of the plurality of charge pumps to be enabled.

7. The internal voltage generating device according to claim 1, wherein the charge pump enable control circuit is configured to receive the plurality of drive strength control signals and a first clock signal, and to generate each of the corresponding enable signals by passing or masking the first clock signal according to each of the drive strength control signals.

8. The internal voltage generating device according to claim 1, wherein the drive strength control circuit comprises:
a drive strength update signal circuit, configured to generate a drive strength update signal based on a transition state of the comparison result; and
a logic circuit, generating a plurality of first signals respectively corresponding to the plurality of drive strength control signals based on the drive strength update signal and current logic values of the plurality of drive strength control signals.

9. The internal voltage generating device according to claim 7, wherein the charge pump enable control circuit comprises:
a plurality of AND gates, respectively coupled to the plurality of charge pumps, wherein each of the AND gates performs a logic AND operation on each of the corresponding drive strength control signals and the clock signal to generate each of the corresponding enable signals.

10. The internal voltage generating device according to claim 8, wherein the drive strength update signal circuit comprises:
a debounce circuit, generating a second signal based on whether a logic value of the comparison result is maintained for a delay period; and
a latch circuit, coupled to the debounce circuit, wherein the latch circuit is configured to set the drive strength update signal to logic value 0 when an inverted second clock signal is at logic value 0, and to generate the drive strength update signal based on a logic value of the second signal when the inverted second clock signal is at logic value 1.

11. The internal voltage generating device according to claim 10, wherein the debounce circuit comprises:
a delay unit, configured to provide the delay time to delay the comparison result to generate a delayed comparison result; and
a logic gate, performing a logic operation on the comparison result and the delayed comparison result to generate the second signal.

12. The internal voltage generating device according to claim 10, wherein the latch circuit comprises:
a first inverter, receiving the inverted second clock signal;
a first transistor, coupled between the first inverter and a reference ground terminal, wherein a control terminal of the first transistor receives the second signal;
a latch, coupled to an output terminal of the first inverter, and configured to generate the drive strength update signal; and
a second inverter, receiving the drive strength update signal to generate an inverted drive strength update signal.

13. The internal voltage generating device according to claim 8, wherein the drive strength control circuit further comprises:
a drive strength generating circuit, coupled to the logic circuit to receive the plurality of first signals, wherein the drive strength generating circuit is configured to respectively latch the plurality of first signals according to an inverted second clock signal, and to transmit the plurality of latched first signals according to a second clock signal to update the plurality of drive strength control signals.

14. The internal voltage generating device according to claim 13, wherein the drive strength generating circuit comprises a plurality of flip-flops, each of the flip-flops comprising:
a first switch, receiving one of the first signals, and controlled by the inverted second clock signal;
a latch circuit, configured to receive and store the one of the first signals through the first switch;
a second switch, coupled to an output terminal of the latch circuit, and controlled by the second clock signal; and
a latch, coupled to the second switch, and configured to receive and store the one of the first signals through the second switch to generate one of the drive strength control signals.

15. A method for generating an internal voltage, comprising:
generating a plurality of enable signals based on a plurality of drive strength control signals, and determining the number of charge pumps to be enabled according to the plurality of enable signals, in order to generate a pump-up voltage through the plurality of charge pumps to be enabled;
comparing an internal voltage with a reference voltage, and determining whether to update each of the drive strength control signals based on a comparison result; and
when it is determined to update, updating the plurality of enable signals according to the plurality of updated drive strength control signals.

16. The method for generating the internal voltage according to claim 15, further comprising:
generating a first clock signal based on the comparison result; and
equating each of the corresponding enable signals to the first clock signal when each of the drive strength control signals is in an enabled state; setting each of the corresponding enable signals to a fixed logic value when each of the drive strength control signals is in a disabled state.

17. The method for generating the internal voltage according to claim 15, wherein the step of determining whether to update the each of the drive strength control signals based on the comparison result comprises:
when the internal voltage is greater than the reference voltage, reducing the number of the plurality of drive strength control signals in an enabled state; and
when the internal voltage is less than the reference voltage, increasing the number of the plurality of drive strength control signals in the enabled state.

18. The method for generating the internal voltage according to claim 15, wherein the number of the plurality of drive strength control signals in an enabled state is equal to the number of the plurality of charge pumps to be enabled.

19. The method for generating the internal voltage according to claim 15, wherein the step of determining whether to update the each of the drive strength control signals based on the comparison result comprises:
periodically comparing the internal voltage with the reference voltage, and determining whether a value of the comparison result remains unchanged within a delay time, and the plurality of enable signals are updated only when the value of the comparison result remains unchanged within the delay time.

20. The method for generating the internal voltage according to claim 15, wherein in response to a command for a programming operation, a pre-programming operation, a soft programming operation, or a refresh operation, a plurality of initial drive strength control signals are read from a non-volatile storage element of a memory device, and the plurality of enable signals are generated based on the plurality of initial drive strength control signals at the beginning of the command.
